(19) United States
(12) Patent Application Publication
(10) Pub. No.: US 2017/0236825 A1
(43) Pub. Date: Aug. 17, 2017

(54) SEMICONDUCTOR INTEGRATED CIRCUIT DEVICE WITH RESERVOIR CAPACITORS AND METHOD OF MANUFACTURING THE SAME

(71) Applicant: SK hynix Inc., Icheon-si Gyeonggi-do (KR)

(72) Inventors: Jong Su KIM, Icheon-si Gyeonggi-do (KR); Dong Kun LEE, Icheon-si Gyeonggi-do (KR)

(21) Appl. No.: 15/184,044

(22) Filed: Jun. 16, 2016

(30) Foreign Application Priority Data
Feb. 11, 2016 (KR) 10-2016-0015494

(51) Int. Cl. H01L 27/108; H01L 23/535; H01L 49/02

(52) U.S. Cl. CPC H01L 27/10829; H01L 28/75; H01L 27/10897; H01L 27/10847; H01L 23/535

(57) ABSTRACT

A semiconductor integrated circuit device may include a semiconductor chip, a power line region and a reservoir capacitor. The semiconductor chip may include a cell region and a peripheral circuit region. The power line region may be arranged on an edge portion of the peripheral circuit region. The reservoir capacitor may be formed on the power line region.

### CROSS-REFERENCES TO RELATED APPLICATION

The present application claims priority under 35 U.S.C. §119(a) to Korean application number 10-2016-0015494, filed on Feb. 11, 2016, in the Korean Intellectual Property Office, which is incorporated herein by reference in its entirety.

### BACKGROUND

1. Technical Field

Various embodiments generally relate to a semiconductor integrated circuit device and a method of manufacturing the same, and more particularly to a reservoir capacitor and a method of manufacturing the reservoir capacitor.

2. Related Art

A semiconductor memory device such as a DRAM may include not only capacitors in memory cells, but also capacitors for supplying stable voltages. For example, in order to supply stable voltages in a high impedance state, a reservoir capacitor may be formed in a portion of a peripheral circuit region.

The reservoir capacitor may remove high-frequency noises from power lines. The reservoir capacitor, when charged, may also supply power to the semiconductor memory device. Further, the reservoir capacitor may improve impedance characteristics when the semiconductor memory device is electrically connected to an external power source.

The reservoir capacitor may generally be formed in the peripheral circuit region because it usually has extra spaces unlike the cell array region. However, as the semiconductor memory device is highly integrated, the integration density of the peripheral circuit region may also be remarkably increased. Thus, it may be difficult to ensure sufficient space for the power line. Further, it may also be difficult to form the reservoir capacitor having a large capacity.

### SUMMARY

According to an embodiment, there may be provided a semiconductor integrated circuit device. The semiconductor integrated circuit device may include a semiconductor chip, a power line region and a reservoir capacitor. The semiconductor chip may include a cell region and a peripheral circuit region. The power line region may be arranged on an edge portion of the peripheral circuit region. The reservoir capacitor may be formed on the power line region.

According to an embodiment, there may be provided a semiconductor integrated circuit device. The semiconductor integrated circuit device may include a semiconductor chip, a power line region, a reservoir capacitor and a via plug. The semiconductor chip may include a cell region and a peripheral circuit region. The power line region may be arranged on an edge portion of the peripheral circuit region. The power line region may include a power line and a dummy power line. The power line may provide a power signal to circuits in the cell region and the peripheral circuit region. The reservoir capacitor may be formed on the power line region. The via plug may be in contact with the power line.

According to an embodiment, there may be provided a method of manufacturing a semiconductor integrated circuit device. In the method of manufacturing the semiconductor integrated circuit device, a power line and a dummy power line may be formed on a semiconductor substrate. An insulating interlayer may be formed on the semiconductor substrate. The insulating interlayer may have a first via hole having a first width configured to expose the power line, and a second via hole having a second width greater than the first width configured to expose the dummy power line. A lower metal layer may be formed on the insulating interlayer to fill up the first via hole. A dielectric layer may be formed on the lower metal layer. An upper metal layer may be formed on the dielectric layer. A planarizing interlayer may be formed on the upper metal layer to fill up the second via hole. The planarizing interlayer, the upper metal layer, the dielectric layer and the lower metal layer may be planarized such that the planarizing interlayer may be expose to form a via plug in the first via hole and a reservoir capacitor in the second via hole.

### BRIEF DESCRIPTION OF THE DRAWINGS

FIG. 1 is a plan view illustrating an example of a semiconductor integrated circuit device in accordance with example embodiments.

FIG. 2 is an enlarged plan view illustrating an example of a leaf cell region of a peripheral region in the semiconductor integrated circuit device.

FIGS. 3 to 13 are cross-sectional views illustrating an example method of manufacturing a semiconductor integrated circuit device in accordance with example embodiments.

FIGS. 14 and 15 are cross-sectional views illustrating an example method of manufacturing a semiconductor integrated circuit device in accordance with example embodiments.

FIG. 16 is a cross-sectional view illustrating an example of a semiconductor integrated circuit device in accordance with example embodiments.

FIG. 17 is a schematic diagram illustrating an example of a memory card according to an embodiment of the present disclosure.

FIG. 18 is a block diagram illustrating an example of an electronic system according to an embodiment of the present disclosure.

FIG. 19 is a block diagram illustrating an example of a data storage apparatus according to an embodiment of the present disclosure.

FIG. 20 is a block diagram illustrating an example of an electronic apparatus according to an embodiment of the present disclosure.

### DETAILED DESCRIPTION

Various example embodiments will be described hereinafter with reference to the accompanying drawings, in which some examples of the embodiments are illustrated. The embodiments may, however, be embodied in many different forms and should not be construed as limited to the examples of embodiments set forth herein. Rather, these examples of embodiments are provided so that this disclosure will be thorough and complete, and will fully convey a scope of the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

The terminology used herein is for the purpose of describing particular examples of embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, examples of the embodiments will be explained with reference to the accompanying drawings.

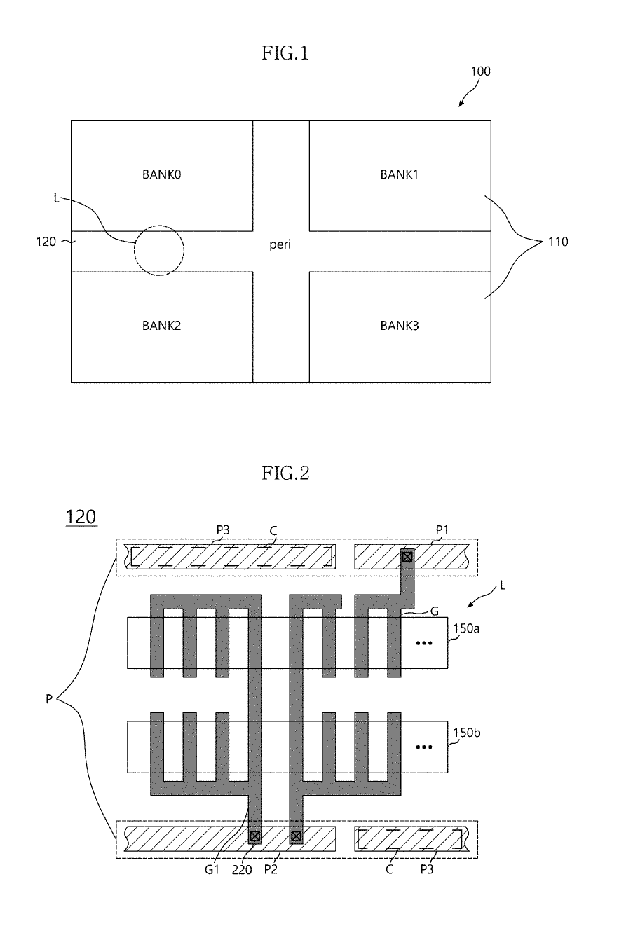

FIG. 1 is a plan view illustrating an example of a semiconductor integrated circuit device in accordance with example embodiments, and FIG. 2 is an enlarged plan view illustrating a leaf cell region of a peripheral region in the semiconductor integrated circuit device.

Referring to FIG. 1, a semiconductor chip 100 may include a cell region 110 and a peripheral circuit region 120. The cell region 110 may include banks BANK0, BANK1, BANK2 and BANK3 in which a plurality of memory cells may be formed. The peripheral circuit region 120 may be positioned between the cell regions 110. Signal generation circuits may be formed in the peripheral circuit region 120 to provide various signals (e.g., control signals) to the cell region 110.

The peripheral circuit region 120 may include a leaf cell region L including logic circuits, a power line region P, and a reservoir capacitor C.

The leaf cell region L may include an NMOS transistor and a PMOS transistor. The leaf cell region L may include an N-well region 150a and a P-well region 150b. The N-well region 150a and the P-well region 150b may be spaced apart from each other. N type impurities may be implanted into the leaf cell region L to form the N-well region 150a. P type impurities may be implanted into the leaf cell region L to form the P-well region 150b. A gate line G and an impurity region corresponding to a designed logic may be formed on the N-well region 150a and the P-well region 150b to form the NMOS transistor and the PMOS transistor.

The power line region P may include a plurality of power lines P1, P2 and P3. The power line region P may be arranged in a portion of the peripheral region 120. For example, the power line region P may be arranged along an edge of the leaf cell region L. The power line region P may extend in a direction in which the N-well region 150a and the P-well region 150b extend. For example, the power line region P may extend in a long axis direction of the N-well region 150a and the P-well region 150b. In example embodiments, the N-well region 150a and the P-well region 150b may extend along each other, and a part of the power line region P may be positioned near the N-well region 150a on the opposite side of where the N-well region 150a faces the P-well region 150b, and another part of the power line region P may be positioned near the P-well region 150b on the opposite side of where the P-well region 150b faces the N-well region 150a. The power lines P1, P2 and P3 may include a supply voltage (VDD) power line P1, a ground voltage line P2 and a dummy power line P3.

The reservoir capacitor C may be formed over the dummy power line P3. For example, the reservoir capacitor C may use the dummy power line P3 as a capacitor electrode thereof. Thus, because the reservoir capacitor C may be formed over the dummy power line P3, the semiconductor chip 100 does not need an extra space for the reservoir capacitor C. As a result, the power line may be formed on a region that would be otherwise occupied by the reservoir capacitor C. In FIG. 2, a reference numeral 220 may indicate a contact plug electrically connecting the gate line G1 to the power lines P1 and P2.

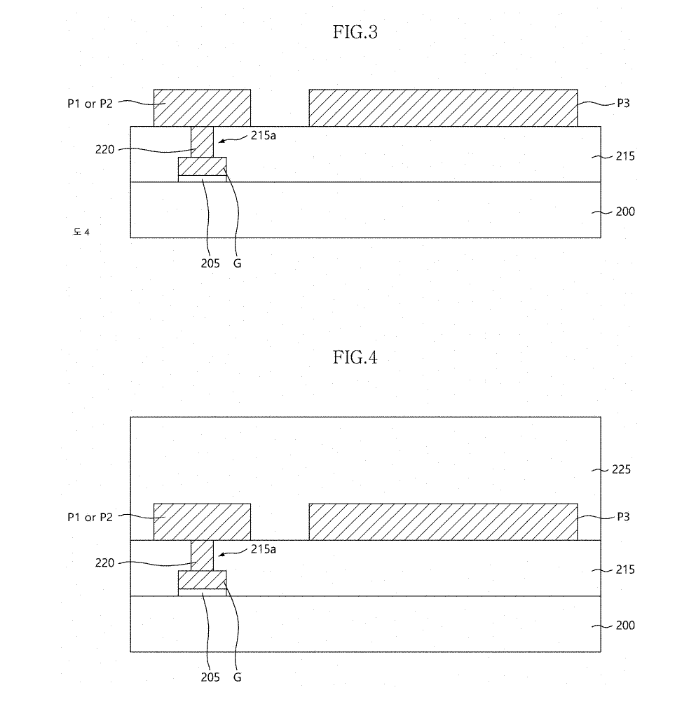

FIGS. 3 to 13 are cross-sectional views illustrating an example method of manufacturing a semiconductor integrated circuit device in accordance with example embodiments.

Referring to FIGS. 2 and 3, a gate insulating layer 205 may be formed on a semiconductor substrate 200 including an N-well region and a P-well region therein. A gate line G may be formed on the gate insulating layer 205. A lower insulating interlayer 215 may be formed over the semiconductor substrate 200 having the gate line G thereon. Examples of the lower insulating layer 215 may include a silicon oxide layer, a silicon nitride layer, a silicon oxy-nitride layer, a low-K dielectric layer, a combination thereof, etc. A portion of the lower insulating layer 215 may be etched to form a contact hole 215a, and a portion of the gate line G may be exposed by etching the portion of the lower insulating layer 215. A conductive layer may be formed on the lower insulating layer 215 to fill the contact hole 215a. The conductive layer may be planarized, and as a result a first contact plug 220 may be formed in the contact hole 215a. A first metal layer may be formed on the lower insulating layer 215. The first metal layer may be patterned to form a power line P1 or P2. Here, the power line P1 or P2 may be in contact with the first contact plug 220. A dummy power line P3 may be formed on a portion of the lower insulating layer 215 adjacent to the power line P1 or P2 simultaneously with the formation of the power line P1 or P2.

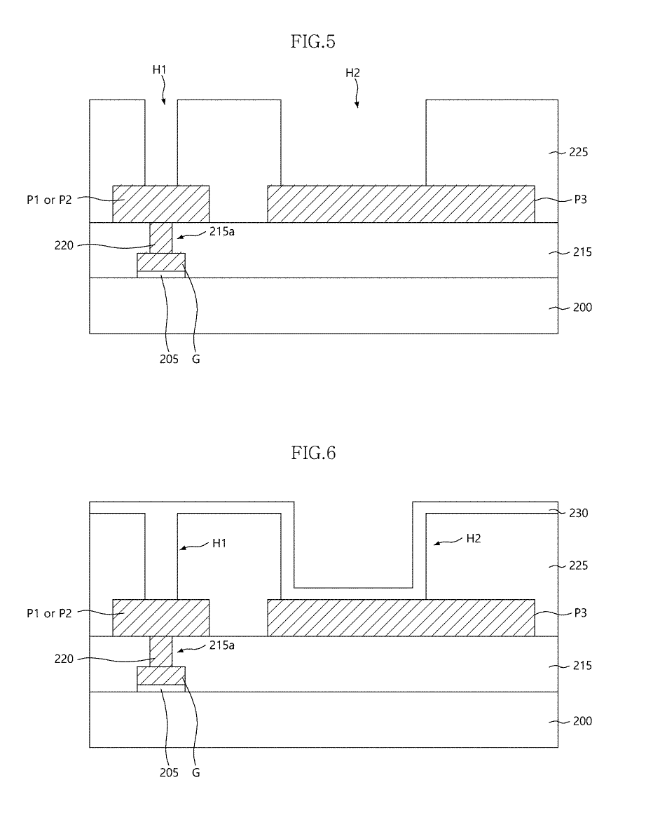

Referring to FIG. 4, a first insulating interlayer 225 may be formed over the lower insulating layer 215 having the power line P1 or P2 and the dummy power line P3 thereon. Examples of the first insulating interlayer 225 may include a silicon oxide layer, a silicon nitride layer, a silicon oxy-nitride layer, a low-K dielectric layer, a combination thereof, etc. A thickness of the first insulating interlayer 225 may be determined in accordance with a capacitance of a reservoir capacitor.

Referring to FIG. 5, portions of the first insulating interlayer 225 may be etched so that a first via hole H1 and a second via hole H2 may be formed and the power line P1 or P2 and the dummy power line P3 may be partially exposed. The second via hole H2 may expose a large portion of the dummy power line P3 to form the reservoir capacitor in the second via hole H2.

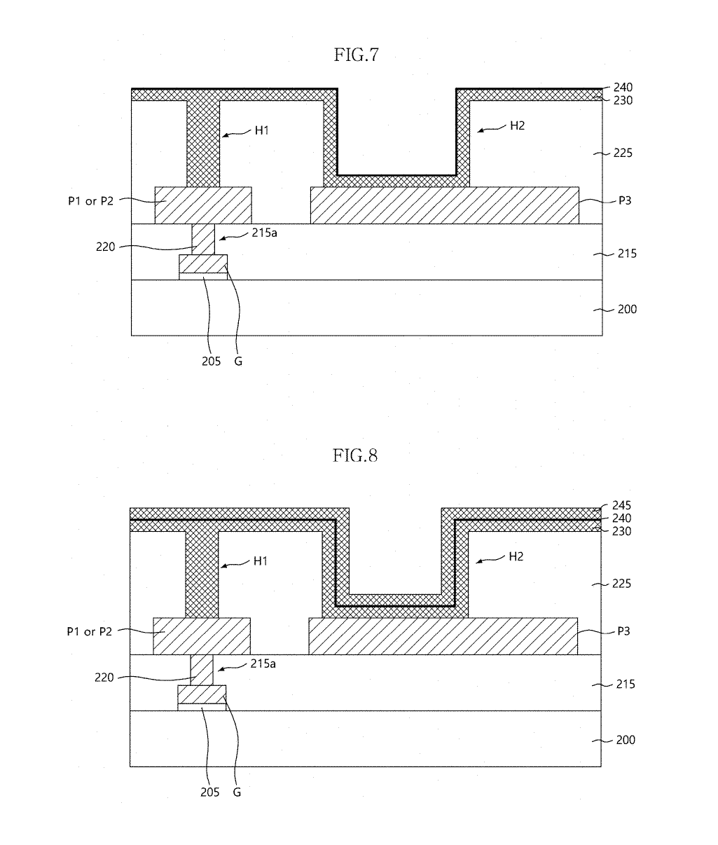

Referring to FIG. 6, a second metal layer 230 may be formed on the first insulating interlayer 225 having the first and second via holes H1 and H2 thereon. The second metal layer 230 may be a conductive layer to form the capacitor. Example materials of the second metal layer 230 may include Ru, RuO, Pt, PtO, Ir, IrO, SRO(SrRuO), BSRO[(Ba,Sr)RuO], CRO(CaRuO), BaRuO, La(Sr,Co)O, Ti, TiN, W, WN, Ta, TaN, TiAlN, TiSiN, TaAlN, TaSiN, a combination thereof, etc. The second metal layer 230 may have a thickness such that the first via hole H1 is filled with the material of the second metal layer 230. The second metal layer 203 may be in contact with an exposed surface of the power line P1 or P2 and the dummy power line P3.

Referring to FIG. 7, a dielectric layer 240 may be formed on the second metal layer 230. The dielectric layer 240 may be formed by an atomic layer deposition (ALD) process. Example materials of the dielectric layer 240 may include TaO, TaAlO, TaON, AlO, HfO, ZrO, ZrSiO, TiO, TiAlO, BST[(Ba,Sr)TiO], STO(SrTiO), BTO(BaTiO), PZT[Pb(Zr,Ti)O], (Pb,La)(Zr,Ti)O, Ba(Zr,Ti)O, Sr(Zr,Ti)O, a combination thereof, etc.

Referring to FIG. 8, a third metal layer 245 may be formed on the dielectric layer 240. The third metal layer 245 may have a conformal thickness along a surface of a resultant structure having the dielectric layer 240. Example materials of the third metal layer 245 may include Ru, RuO, Pt, PtO, Ir, IrO, SRO(SrRuO), BSRO[(Ba,Sr)RuO], CRO(CaRuO), BaRuO, La(Sr,Co)O, Ti, TiN, W, WN, Ta, TaN, TiAlN, TiSiN, TaAlN, TaSiN, a combination thereof, etc.

Referring to FIG. 9, a second insulating interlayer 250 may be formed on the third metal layer 245. The second insulating interlayer 250 may be formed such that the second via hole H2 is filled with the second insulating interlayer 250.

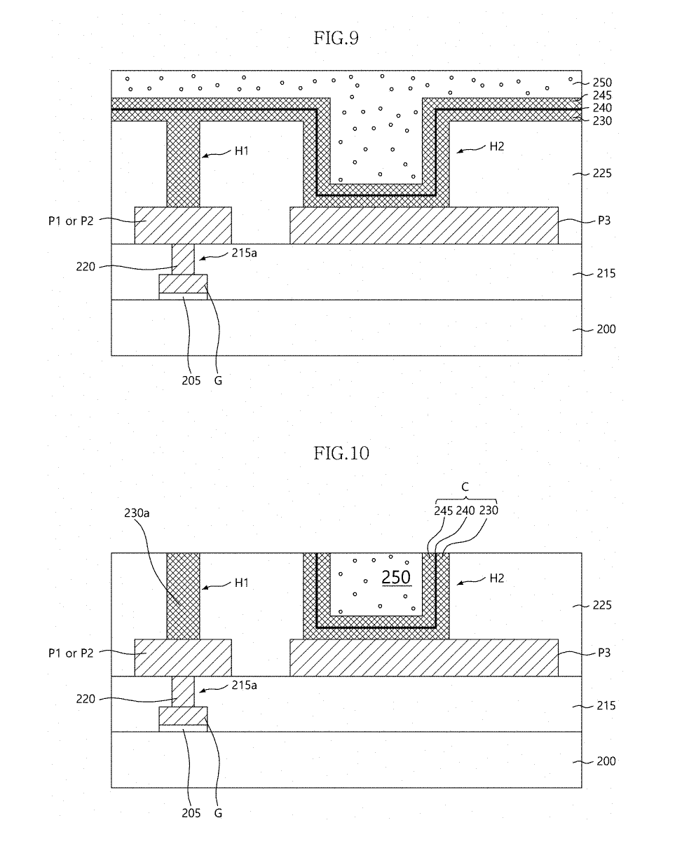

Referring to FIG. 10, the second insulating interlayer 250, the third metal layer 245, the dielectric layer 240 and the second metal layer 230 may be planarized such that the first insulating interlayer 225 is exposed. In this way, a via plug 230a and a reservoir capacitor C may be formed. The second metal layer 230 may correspond to a lower electrode of the reservoir capacitor C. The third metal layer 245 may correspond to an upper electrode of the reservoir capacitor C. The planarizing process may include a chemical mechanical polishing (CMP) process.

Referring to FIG. 11, a third via hole H3 may be formed by partially removing the second insulating interlayer 250. The upper electrode of the reservoir capacitor C (i.e., the third metal layer 245) may be partially exposed by the third via hole H3.

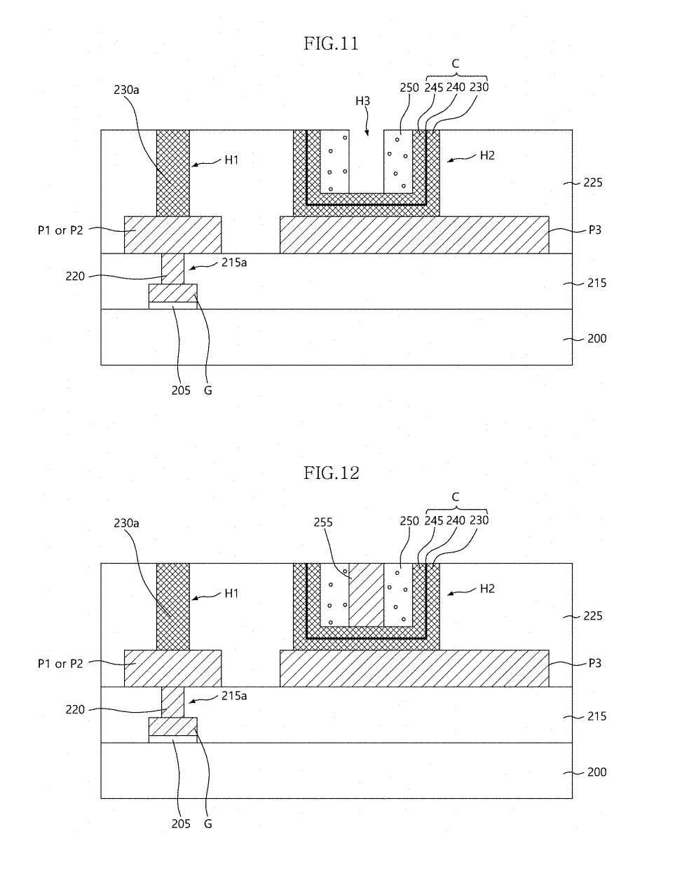

Referring to FIG. 12, the third via hole H3 may be filled with a fourth metal layer. The fourth metal layer may be planarized such that the first insulating interlayer 225 and the second insulating interlayer 250 are exposed. In this way, an upper electrode plug 255, which is in contact with the third metal layer 245 corresponding to the upper electrode, may be formed.

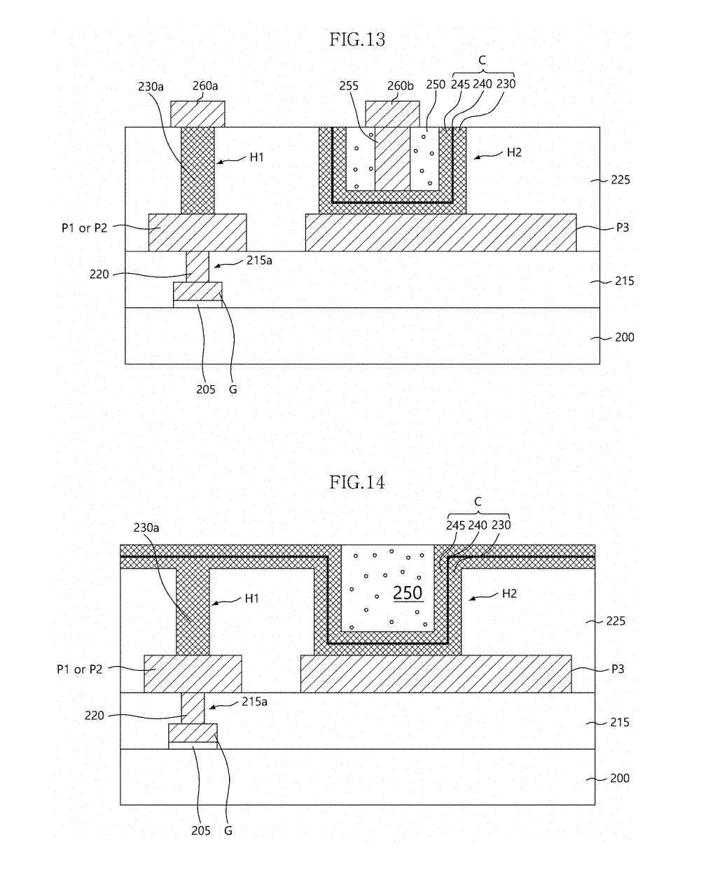

Referring to FIG. 13, a fifth metal layer may be formed on the first insulating interlayer 225 and the second insulating interlayer 250. The fifth metal layer may be patterned to form wiring patterns 260a and 260b, which are in contact with the via plug 230a and the upper electrode plug 255, respectively. The reservoir capacitor C may store electrical energy (for example, data, information, etc.) provided from the dummy power line P3 and the wiring pattern 260b to the lower electrode 230 and the upper electrode 245.

According to an example embodiment, the reservoir capacitor C may be formed on the dummy power line P3 in the peripheral region 120. Thus, the peripheral region 120 does not need an extra space for the reservoir capacitor C. Therefore, an area that would be otherwise occupied by the reservoir capacitor C may be used for the power line. As a result, wiring noises and wiring resistances may be reduced by securing the area for the power line. Further, because the reservoir capacitor C may be formed in the insulating interlayer over the dummy power line, a capacitance of the reservoir capacitor C may be controlled by adjusting the thickness of the insulating interlayer.

FIGS. 14 and 15 are cross-sectional views illustrating an example method of manufacturing a semiconductor integrated circuit device in accordance with example embodiments.

Processes for forming the second insulating interlayer 250 to fill the second via hole H2 may be substantially the same as those discussed with reference to FIGS. 3 to 9, and thus any repetitive detailed description will be omitted or simplified.

Referring to FIG. 14, the second insulating interlayer 250 may be planarized such that the third metal layer 245 is exposed.

Referring to FIG. 15, a mask pattern (not illustrated) may be used to define a region where the reservoir capacitor C is going to be formed. For example, the mask pattern may be used to define regions in which the dummy power line P3 and the second via hole H2 are going to be formed. The third metal layer 245, the dielectric layer 240 and the second metal layer 235 may be formed using patterning process to define the reservoir capacitor C. For example, the patterning process may include an anisotropic etching process. The first via hole H1 may be defined by the anisotropic etching process, and a via plug 230a may be formed in the first via hole H1.

By defining the reservoir capacitor C using the mask pattern, portions of the second metal layer 230, the dielectric layer 240 and the third metal layer 245 of the reservoir capacitor C may be positioned over the first insulating interlayer 225. Further, an upper surface of the second insulating interlayer 250 may be positioned higher than an upper surface of the first insulating interlayer 225.

An insulating layer may be formed over the first insulating interlayer 225 and the reservoir capacitor C. The insulating layer may be anisotropically etched to form an insulating spacer 252 on a sidewall of the reservoir capacitor C.

A metal layer may be formed on the first insulating interlayer 225 and the reservoir capacitor C. The metal layer may be patterned to form wiring patterns 260a and 260b on the via plug 230a and the third metal layer 245.

Thus, a process for forming the upper electrode plug 255 to electrically connect the upper electrode of the reservoir capacitor C to the wiring pattern may be omitted. Further, the insulating spacer 252 formed on the sidewall of the reservoir capacitor C may insulate the wiring patterns 260a and 260b from each other.

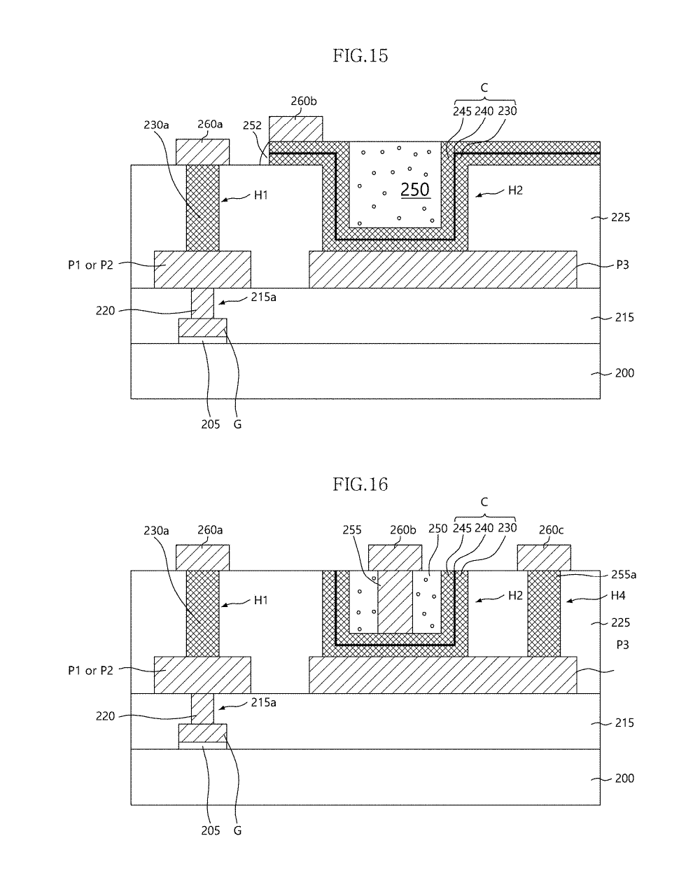

FIG. 16 is a cross-sectional view illustrating an example of a semiconductor integrated circuit device in accordance with example embodiments.

Referring to FIG. 16, the first insulating interlayer 225 may be etched to form an additional via hole H4 exposing the dummy power line P3. The etching process for forming the via hole H4 may be performed simultaneously with forming the first and second via holes H1 and H2. Alternately, the etching process for forming the via hole H3 may be performed simultaneously with forming the via hole H3 for exposing the upper electrode 245.

The process for forming the upper electrode plug 255 or the via plug and the process for forming the wiring patterns 260a and 260b may be performed to form a dummy plug 255a and a dummy power wiring 260c which are in contact with the dummy power line P3. Thus, the dummy power line P3 may receive a voltage from the dummy power wiring 260c.

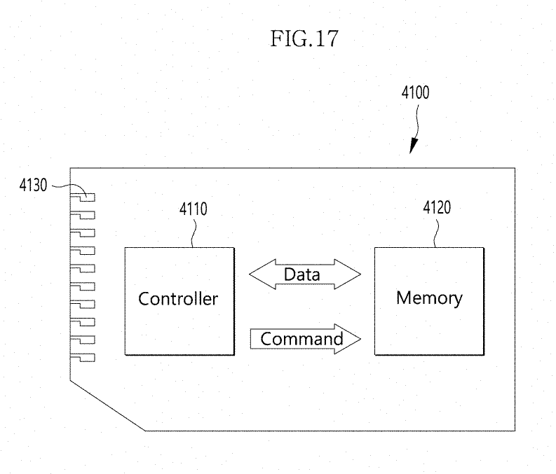

FIG. 17 is a schematic diagram illustrating an example of a memory card having a semiconductor integrated circuit device according to various embodiments of the present disclosure.

Referring to FIG. 17, a memory card system 4100 may include a controller 4110, a memory 4120, and an interface member 4130 may be provided. The controller 4110 may provide a command to the memory 4120, and the controller 4110 and the memory 4120 may exchange data. For example, the memory 4120 may be used to store a command to be executed by the controller 4110. The memory 4120 may also be used to store user data.

The memory card system 4100 may store data in the memory 4120 or output data from the memory 4120 to an external device. The memory 4120 may include the semiconductor integrated circuit device including the reservoir capacitor according to various embodiments.

The interface member 4130 may be used to input and output data from and to the external device. The memory card system 4100 may be a multimedia card (MMC), a secure digital card (SD) or a portable data storage device.

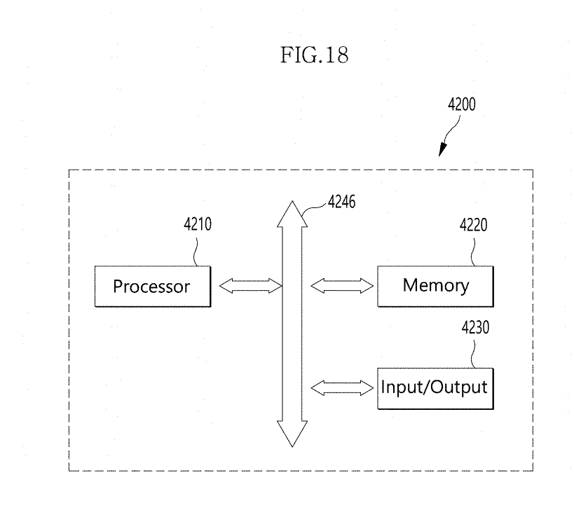

FIG. 18 is a block diagram illustrating an example of an electronic apparatus having a semiconductor integrated circuit device according to various embodiments of the disclosure.

Referring to FIG. 18, an electronic apparatus 4200 including a processor 4210, a memory 4220, and an input/output (I/O) device 4230 may be provided. The processor 4210, the memory 4220, and the I/O device 4230 may be electrically coupled to one another through a bus 4246.

The memory 4220 may receive a control signal from the processor 4210. The memory 4220 may store a code and data for operating the processor 4210. The memory 4220 may be used to store data transmitted through the bus 4246.

The memory 4220 may include the semiconductor integrated circuit device including the reservoir capacitor according to various embodiments.

The electronic apparatus 4200 may constitute any one of various electronic control apparatuses having the memory 4220. For example, the electronic apparatus 4200 may be used in a computer system or a wireless communication device, such as a personal digital assistant (PDA), a laptop computer, a portable computer, a web tablet, a wireless phone, a portable phone, a digital music player, an MP3 player, a navigator, a solid state disk (SSD), a household appliance, or any device capable of transmitting and receiving wireless information.

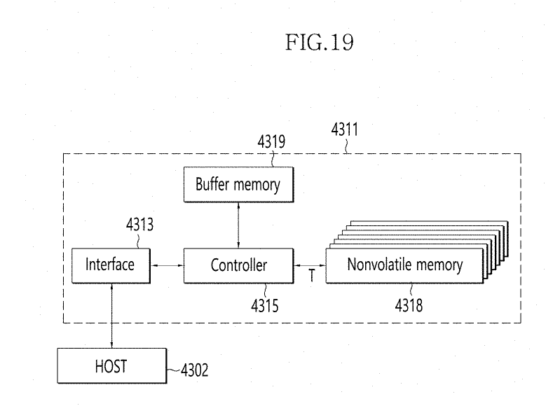

FIG. 19 is a block diagram illustrating an example data storage apparatus having a semiconductor integrated circuit device according to various embodiments of the disclosure.

Referring to FIG. 19, a data storage apparatus 4311 such as a solid state disk (SSD) may be provided. The SSD 4311 may include an interface 4313, a controller 4315, a nonvolatile memory 4318, and a buffer memory 4319.

The SSD 4311 may be an apparatus that stores information using a semiconductor device. The SSD 4311 may be used in a laptop PC, a netbook, a desktop PC, an MP3 player, or a portable storage device.

The controller 4315 may be electrically coupled to the interface 4313. The controller 4315 may be a microprocessor including a memory controller and a buffer controller. The nonvolatile memory 4318 may be electrically coupled to the controller 4315 via a connection terminal T. The data storage capacity of the SSD 4311 may vary depending on how large the data storage capacity of the nonvolatile memory 4318 is. The buffer memory 4319 may be electrically coupled to the controller 4315.

The interface 4313 may be electrically coupled to a host 4302. The interface 4313 may transmit and receive electrical signals such as data signals to and from the host 4302. For example, the interface 4313 may be a device that uses the same standard as SATA, IDE, SCSI, and/or a combination thereof. The nonvolatile memory 4318 may be electrically coupled to the interface 4313 via the controller 4315.

The nonvolatile memory 4318 may store data received through the interface 4313.

The nonvolatile memory 4318 may include the semiconductor integrated circuit device manufactured according to various embodiments. The nonvolatile memory 4318 has a characteristic that stored data is retained even when power supply to the SSD 4311 is interrupted.

The buffer memory 4319 may include a volatile memory. The volatile memory may be a DRAM and/or an SRAM. The buffer memory 4319 has a relatively high operation speed than the nonvolatile memory 4318.

The data processing speed of the interface 4313 may be faster than the operation speed of the nonvolatile memory 4318. The buffer memory 4319 may temporarily store data. The data received through the interface 4313 may be transferred to the buffer memory 4319 via the controller 4315, and the data may be temporarily stored in the buffer memory 4319. The data may then be stored in the nonvolatile memory 4318.

Among the data stored in the nonvolatile memory 4318, frequently used data may be read in advance and temporarily stored in the buffer memory 4319. In this way, the buffer memory 4319 may increase the effective operation speed of the SSD 4311 and reduce an error occurrence rate.

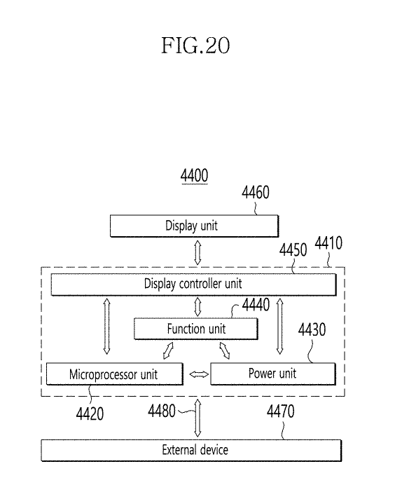

FIG. 20 is a system block diagram illustrating an example of an electronic apparatus having a semiconductor integrated circuit device according to various embodiments of the disclosure.

Referring to FIG. 20, an electronic system 4400 including a body 4410, a microprocessor unit 4420, a power unit 4430, a function unit 4440, and a display controller unit 4450 may be provided.

The body 4410 may be a mother board formed of a printed circuit board (PCB). The microprocessor unit 4420, the power unit 4430, the function unit 4440, and the display controller unit 4450 may be mounted on the body 4410. A display unit 4460 may be disposed inside the body 4410 or outside the body 4410. For example, the display unit 4460 may be disposed on a surface of the body 4410. The display unit 4460 may also display images processed by the display controller unit 4450.

The power unit 4430 may receive a voltage from an external battery or the like, and divide the voltage into desired voltage levels to supply divided voltages to the microprocessor unit 4420, the function unit 4440, the display controller unit 4450, and so forth. The microprocessor unit 4420 may receive a voltage from the power unit 4430 and control the function unit 4440 and the display unit 4460. The function unit 4440 may perform various functions of the electronic system 4400. For example, when the electronic system 4400 is a portable phone, the function unit 4440 may include various components capable of performing portable phone functions, such as output of an image to the display unit 4460 or output of a voice to a speaker while communicating with an external device 4470. When a camera is mounted on the body 4410, the function unit 4440 may serve as an image processor.

When the electronic system 4400 is electrically coupled to a memory card or the like to increase capacity, the function unit 4440 may be a memory card controller. The function unit 4440 may exchange signals with the external device 4470 through a wired or wireless communication unit 4480. When the electronic system 4400 needs a universal serial bus (USB) or the like to expand functions, the function unit 4440 may serve as an interface controller. Any one of the semiconductor integrated circuit devices according to various embodiments may be applied to at least one of the microprocessor unit 4420 and the function unit 4440.

The above embodiments of the present disclosure are illustrative and not limitative. Various alternatives and equivalents are possible. The examples of the embodiments are not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. A semiconductor integrated circuit device comprising:
a semiconductor chip including a cell region and a peripheral circuit region;
a power line region arranged on an edge portion of the peripheral circuit region; and
a reservoir capacitor arranged on the power line region.

2. The semiconductor integrated circuit device of claim 1, wherein the power line region comprises a supply voltage power line, a ground voltage line, and a dummy power line.

3. The semiconductor integrated circuit device of claim 2, wherein the reservoir capacitor is arranged over the dummy power line in the power line region.

4. The semiconductor integrated circuit device of claim 1, further comprising an insulating interlayer covering the power line region, wherein the reservoir capacitor is arranged in the insulating interlayer.

5. The semiconductor integrated circuit device of claim 1, wherein the reservoir capacitor comprises:
a lower electrode layer in contact with a dummy power line in the power line region;
a dielectric layer formed on the lower electrode layer; and
an upper electrode layer formed on the dielectric layer.

6. The semiconductor integrated circuit device of claim 5, further comprising a wiring pattern electrically connected to the upper electrode layer.

7. The semiconductor integrated circuit device of claim 5, further comprising a wiring pattern electrically connected to the dummy power line.

8. A semiconductor integrated circuit device comprising:
a semiconductor chip including a cell region and a peripheral circuit region;
a power line region arranged on an edge portion of the peripheral circuit region, the power line region including a power line and a dummy power line, the power line providing a power signal to circuits in the cell region and the peripheral region; and
a reservoir capacitor arranged on the dummy power line; and
a via plug in contact with the power line.

9. The semiconductor integrated circuit device of claim 8, further comprising an insulating interlayer formed on the semiconductor chip, the insulating interlayer including a first via hole and a second via hole, the first via hole receiving the via plug, the second via hole receiving the reservoir capacitor.

10. The semiconductor integrated circuit device of claim 9, wherein the reservoir capacitor comprises:
a lower electrode layer formed on an inner surface of the second via hole, the lower electrode layer including a material substantially the same as that of the via plug;
a dielectric layer formed on the lower electrode layer; and
an upper electrode layer formed on the dielectric layer.

11. The semiconductor integrated circuit device of claim 10, further comprising a planarizing interlayer formed on the upper electrode layer to fill the second via hole.

12. The semiconductor integrated circuit device of claim 11, further comprising:
an upper electrode plug formed on the planarizing interlayer; and
a wiring pattern formed on the upper electrode plug.

13. The semiconductor integrated circuit device of claim 10, wherein the reservoir capacitor has a portion extending over the insulating interlayer, the upper electrode layer of a portion of the reservoir capacitor is in direct contact with a wiring pattern.

14. The semiconductor integrated circuit device of claim 13, further comprising an insulating spacer formed on a sidewall of the portion of the reservoir capacitor.

15. The semiconductor integrated circuit device of claim 8, further comprising a wiring pattern formed on the via plug.

16. The semiconductor integrated circuit device of claim 8, further comprising a dummy power wiring configured to supply a voltage to the dummy power line.

17. A method of manufacturing a semiconductor integrated circuit device, the method comprising:
forming a power line and a dummy power line on a semiconductor substrate;
forming an insulating interlayer on the semiconductor substrate;
forming a first via hole and a second via hole through the insulating interlayer, the first via hole having a first width to expose the power line, and the second via hole having a second width greater than the first width to expose the dummy power line;
forming a lower electrode layer on the insulating interlayer to fill up the first via hole;
forming a dielectric layer on the lower electrode layer;
forming an upper electrode layer on the dielectric layer;
forming planarizing interlayer on the upper electrode layer to fill up the second via hole; and
planarizing the planarizing interlayer, the upper electrode layer, the dielectric layer and the lower electrode layer such that the insulating interlayer is exposed to form a via plug in the first via hole and a reservoir capacitor in the second via hole.

18. The method of claim 17, further comprising:
etching the planarizing interlayer to form a via hole exposing the upper electrode layer;
filling the via hole with a metal layer to form an upper electrode plug; and
forming a wiring pattern in contact with the via plug and the upper electrode plug.

19. The method of claim 18, further comprising:
etching the insulating interlayer simultaneously with forming the via hole such that the dummy power line is exposed to form an additional via hole;
filling the additional via hole with a metal layer to form a dummy plug; and
forming a dummy power wiring on the dummy plug.

20. The method of claim 18, further comprising:
etching the insulating interlayer simultaneously with forming the first and second via holes such that the dummy power line is exposed to form an additional via hole;
filling the additional via hole with a metal layer to form a dummy plug; and
forming a dummy power wiring on the dummy plug.
